(19) United States
(12) Patent Application Publication
(10) Pub. No.: US 2014/0203304 A1
(43) Pub. Date: Jul. 24, 2014

(54) LIGHT-EMITTING DEVICE PACKAGE STRIP AND METHOD FOR MANUFACTURING THE SAME

(71) Applicant: SAMSUNG ELECTRONICS CO., LTD., Suwon-si (KR)

(72) Inventors: Dae-hyun KIM, Hwaseong-si (KR); Wan-jong KIM, Hwaseong-si (KR); Jung-jin KIM, Hwaseong-si (KR); Jung-kyu PARK, Seoul (KR); Kyu-ho JANG, Suwon-si (KR)

(73) Assignee: SAMSUNG ELECTRONICS CO., LTD., Suwon-si (KR)

(21) Appl. No.: 14/095,445

(22) Filed: Dec. 3, 2013

(30) Foreign Application Priority Data
Jan. 22, 2013 (KR) 10-2013-0007092

(51) Int. Cl. H01L 33/52; H05K 7/00; H01L 27/15

(52) U.S. Cl. CPC H01L 33/52; H01L 27/15; H05K 7/005
USPC 257/88; 264/272.14; 174/529

(57) ABSTRACT

Provided is a light-emitting device package strip that includes a lead frame strip, a plurality of resin molding products that are injection-molded in the lead frame strip, and runner and gate members that are formed between adjacent resin molding products and on end sides of a line of adjacent resin molding products, each runner and gate member having a smaller thickness than a thickness of the resin molding products to facilitate cutting thereof.

### CROSS-REFERENCE TO RELATED APPLICATIONS

This application claims the benefit of priority to Korean Patent Application No. 10-2013-0007092, filed on Jan. 22, 2013, in the Korean Intellectual Property Office, the entire contents of which are hereby incorporated by reference.

### TECHNICAL FIELD

The present disclosure relates to a light-emitting device package strip, and more particularly, to a light-emitting device package strip that may improve the efficiency of use of resin.

### BACKGROUND

Generally, to manufacture a light-emitting device package, a plurality of unit light-emitting device packages are arranged in a matrix form or in a line on one lead frame strip, and a resin mold material is molded in the lead frame strip, thus forming a light-emitting device package strip. The light-emitting device package strip may be divided into separate light-emitting device package units after passing through a cutting process.

Typically, a runner and a gate are not formed between a resin mold and its adjacent resin mold. Instead, separate branch-type runner and gate that are connected with corresponding resin molds, respectively, are formed in a port. As a result, a lot of resin mold materials are discarded, degrading the efficiency of the use of resin.

Accordingly, a need exists for a method of maximizing the use efficiency of resin in manufacturing a light-emitting device package.

### SUMMARY

The present disclosure relates to a light-emitting device package strip, in which the thickness and position of a runner and gate member are adjusted to facilitate a cutting process, thereby achieving improvement in resin use efficiency and reduction in production cost and production time, thus improving productivity, and minimizing damage in a side of a resin mold during the cutting process.

An aspect of the present disclosure relates to a light-emitting package strip including a lead frame strip, a plurality of resin molding products that are injection-molded in the lead frame strip, and runner and gate members that are disposed between adjacent resin molding products and on end sides of a line of adjacent resin molding products, the runner and gate members each having a smaller thickness than a thickness of the resin molding products to facilitate cutting thereof.

The runner and gate members may have a smaller thickness than a thickness of the lead frame strip.

The runner and gate members may be disposed in a space between an extending surface of a top surface of the lead frame strip and an extending surface of a bottom surface of the lead frame strip.

The runner and gate members may have a smaller thickness than a thickness of the lead frame strip and may be disposed in one of an upper portion, a middle portion, and a lower portion of an inner space between an extending surface of a top surface of the lead frame strip and an extending surface of a bottom surface of the lead frame strip.

The runner and gate members may have a smaller width than a width of the resin molding products.

The runner and gate members may be disposed along a center line that connects the centers of the line of adjacent resin molding products.

The runner and gate members may be disposed in a zigzag form such that the runner and gate members are disposed alternately to the left and right of a center line that connects the centers of the line of adjacent resin molding products.

The resin molding products may be generally in a hexahedral shape, and the runner and gate members may be disposed in a zigzag form such that the runner and gate members are disposed alternately at a left-side corner and a right-side corner of the resin molding products with respect to a center line that connects the centers of the line of adjacent resin molding products.

The runner and gate members may be of an inclined type that is disposed inclinedly.

The runner and gate members may have one or more of a straight-bent form, a curvilinear-bent form, and a combination thereof.

The runner and gate members may each include a neck portion having a thickness smaller than other portions of the runner and gate member.

The neck portions may have one or more of a V shape, a U shape, and a combination thereof.

The neck portions may be disposed in one or more of an upper portion and a lower portion of the runner and gate members and a combination thereof.

The neck portions may be disposed at both end portions of the runner and gate members.

Another aspect of the present disclosure relates to a light-emitting package strip including a lead frame strip, a plurality of light-emitting devices that are installed in the lead frame strip and disposed spaced apart from each other in a line, a plurality of resin molding products that are injection-molded in the lead frame strip to enclose the light-emitting devices, and runner and gate members that are formed in the resin molding products, connecting adjacent resin molding products to other, and are disposed in an inner space between an extending surface of a top surface of the lead frame strip and an extending surface of a bottom surface of the lead frame strip.

Another aspect of the present disclosure relates to a method of manufacturing a light-emitting package strip. The method may include providing a lead frame strip and providing a mold. The method may also include disposing the plurality of light-emitting devices spaced apart in a line in the mold and forming a plurality of resin molded products enclosing the plurality of light-emitting devices. The method may further include forming runner and gate members between adjacent resin molded products and at the ends of the first and last resin molded products in the line.

The thickness of the runner and gate members may be smaller than the thickness of the resin molded products.

The method may further include removing the runner and gate members from the light-emitting package strip.

The method may also include cutting along bridge cutting lines and lead cutting lines of the light-emitting package strip, providing separate light-emitting device packages.

### BRIEF DESCRIPTION OF THE DRAWINGS

The foregoing and other features of the present disclosure will be apparent from more particular description of embodiments of the inventive concept, as illustrated in the accompanying drawings in which like reference characters may refer to the same or similar elements throughout the different views. The drawings are not necessarily to scale, emphasis instead being placed upon illustrating the principles of the embodiments of the inventive concept. In the drawings, the thickness of layers and regions may be exaggerated for clarity.

Exemplary embodiments of the present disclosure will be more clearly understood from the following detailed description taken in conjunction with the accompanying drawings in which:

FIG. 1 is a top plan view illustrating a light-emitting device package strip according to some embodiments of the present disclosure;

FIG. 2 is a perspective view of FIG. 1;

FIG. 3 is a cross-sectional view cut along a line III-III of FIG. 2;

FIG. 4 is a top plan view illustrating a state in which a runner and gate member is removed from a light-emitting device package strip of FIG. 1 using a cutting process;

FIG. 5 is a perspective view of FIG. 4;

FIG. 6 is a cross-sectional view cut along a line VI-VI of FIG. 5;

FIG. 7 is a top plan view illustrating a light-emitting device package strip according to some embodiments of the present disclosure;

FIG. 8 is a perspective view of FIG. 7;

FIG. 9 is a top plan view illustrating a light-emitting device package strip according to some embodiments of the present disclosure;

FIG. 10 is a top plan view illustrating a light-emitting device package strip according to some embodiments of the present disclosure;

FIG. 11 is a cross-sectional view illustrating a light-emitting device package strip according to some embodiments of the present disclosure;

FIG. 12 is a cross-sectional view illustrating a light-emitting device package strip according to some embodiments of the present disclosure;

FIG. 13 is a cross-sectional view illustrating a light-emitting device package strip according to some embodiments of the present disclosure;

FIG. 14 is an enlarged cross-sectional view illustrating a runner and gate member according to another example of FIG. 3;

FIG. 15 is an enlarged cross-sectional view illustrating a runner and gate member according to still another example of FIG. 3;

FIG. 16 is an enlarged cross-sectional view illustrating a runner and gate member according to further another example of FIG. 3;

FIG. 17 is an enlarged cross-sectional view illustrating a runner and gate member according to yet another example of FIG. 3;

FIG. 18 is an enlarged cross-sectional view illustrating an example of a neck portion of a light-emitting device package strip according to some embodiments of the present disclosure;

FIG. 19 is an enlarged cross-sectional view illustrating another example of a neck portion of a light-emitting device package strip according to some embodiments of the present disclosure;

FIG. 20 is an enlarged cross-sectional view illustrating still another example of a neck portion of a light-emitting device package strip according to some embodiments of the present disclosure;

FIG. 21 is an enlarged cross-sectional view illustrating further another example of a neck portion of a light-emitting device package strip according to some embodiments of the present disclosure;

FIG. 22 is a top plan view illustrating a light-emitting device package strip according to some embodiments of the present disclosure;

FIG. 23 is a perspective view of FIG. 22;

FIG. 24 is a top plan view illustrating a state in which a runner and gate member is removed from a light-emitting device package strip of FIG. 22 using a cutting process;

FIG. 25 is a perspective view of FIG. 24;

FIG. 26 is a top plan view illustrating a state in which a bridge is cut along a bridge cutting line and illustrating a lead cutting line in FIG. 24;

FIG. 27 is a perspective view of FIG. 26; and

FIG. 28 is a flowchart illustrating a process of processing a light-emitting device package strip according to some embodiments of the present disclosure.

### DETAILED DESCRIPTION OF THE EMBODIMENTS

Hereinafter, several embodiments of the present disclosure will be described in detail with reference to the accompanying drawings.

The exemplary embodiments of the present disclosure are provided to more fully describe the present disclosure to those of ordinary skill in the art. The following exemplary embodiments may be modified to various types and the scope of the present disclosure is not limited to the following embodiments. Rather, these embodiments are provided so that this disclosure will be thorough and complete, and will fully convey the spirit of the present disclosure to those skilled in the art.

It will be understood that when an element, such as a layer, a region, or a substrate, is referred to as being “on,” “connected to”, “stacked”, or “coupled to” another element, it may be directly on, connected, stacked, or coupled to the other element or intervening elements may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

As used herein, terms such as “first,” “second,” etc. are used to describe various members, regions, and/or portions. However, it is obvious that the members, components, regions, layers, and/or portions should not be defined by these terms. The terms do not mean a particular order, up and down, or superiority, and are used only for distinguishing one member, part, region, layer, or portion from another member, region, layer, or portion. Thus, a first member, part, region, layer, or portion which will be described may also refer to a second member, part, region, layer, or portion, without departing from the teaching of the present disclosure.

Spatially relative terms, such as “above” or “upper” and “below” or “lower” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” other elements or features would then be oriented “above” the other elements or features. Thus, the exemplary term “above” may encompass both an orientation of above and below. The device may be otherwise oriented (rotated 90 degrees or at other orientations) and the spatially relative descriptors used herein interpreted accordingly.

The terms used herein are for illustrative purposes of the present disclosure only and should not be construed to limit the meaning or the scope of the present disclosure. As used in this specification, a singular form may, unless definitely indicating a particular case in terms of the context, include a plural form. Also, the expressions “comprise” and/or “comprising” used in this specification neither define the mentioned shapes, numbers, steps, operations, members, elements, and/or groups of these, nor exclude the presence or addition of one or more other different shapes, numbers, steps, operations, members, elements, and/or groups of these, or addition of these. The term “and/or” used herein includes any and all combinations of one or more of the associated listed items.

Hereinafter, exemplary embodiments of the present disclosure will be described with reference to the attached drawings that schematically illustrate the ideal embodiments of the present disclosure. In the drawings, for example, according to the manufacturing technology and/or tolerance, the modification of the illustrated shape may be expected. Thus, the exemplary embodiments of the present disclosure must not be interpreted to be limited by a particular shape that is illustrated in the drawings and must include a change in the shape occurring, for example, during manufacturing.

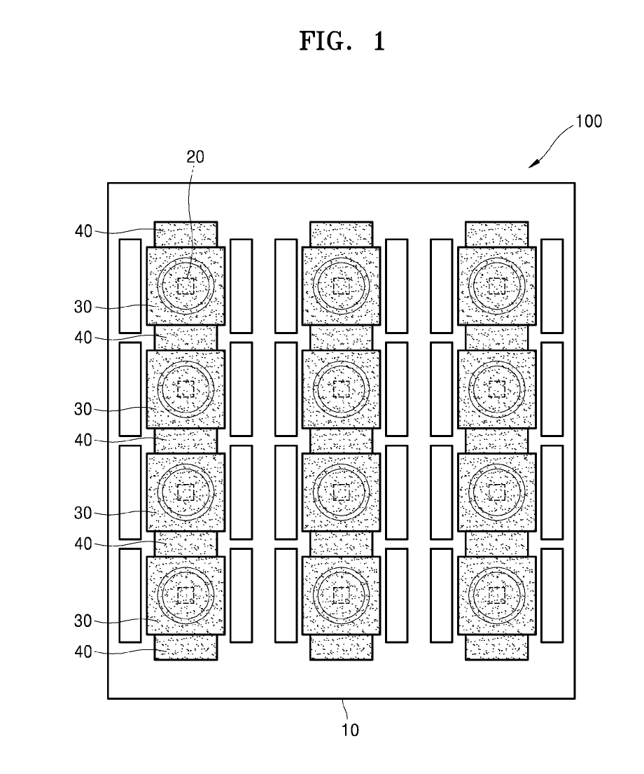

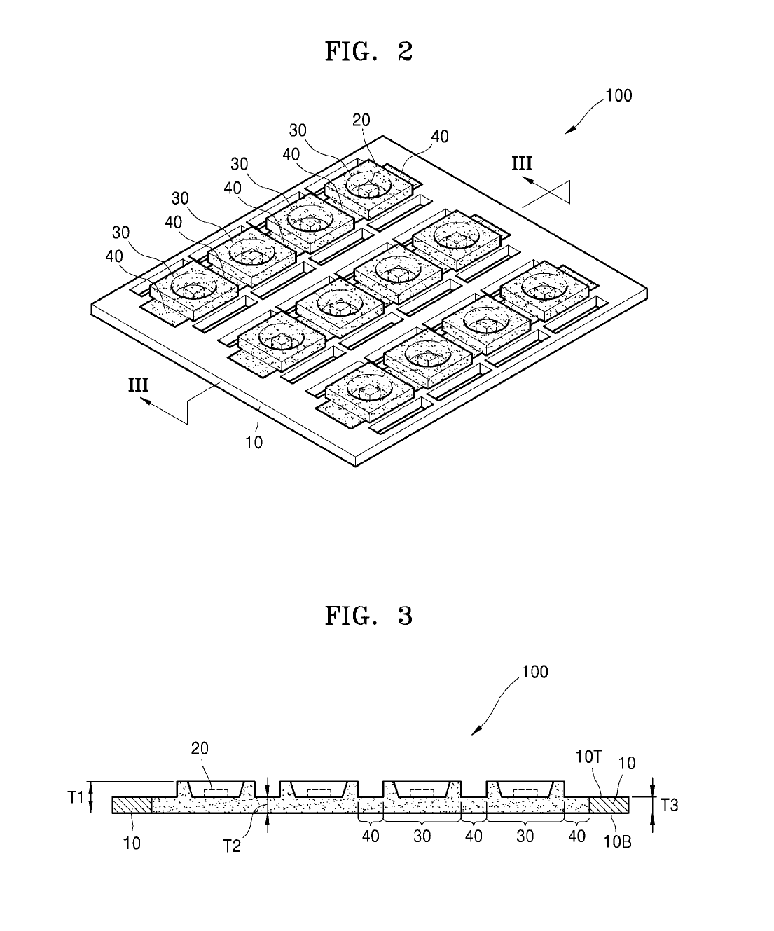

As illustrated in FIGS. 1 through 3, a light-emitting device package strip 100 according to some embodiments of the present invention may include a lead frame strip 10, light-emitting devices 20, resin molding products 30, and runner and gate members 40.

The lead frame strip 10 is a sort of plate that supports the rein molding products 30 and the runner and gate members 40 such that the plurality of resin molding products 30 are connected by the runner and gate members 40 and are arranged in a matrix form or in a line or multiple lines.

Herein, the lead frame strip 10 may be such that lead frames form one structure together, in which each of the lead frames includes a die pad on which the light-emitting device 20 is placed for convenience of working, a lead which electrically connects the light-emitting device 20 to an outside element, a frame formed in an edge, and a bridge which connects the lead with the frame.

The lead frame strip 10 is an alloy frame for electrically connecting the light-emitting devices 20 with an external circuit during a light-emitting device package assembly process. The lead frame strip 10 supports the light-emitting devices 20 and may be formed of an iron-based alloy, a copper-based alloy, or the like.

For example, the iron-based alloy has a low thermal expansion coefficient and a high strength. The most representative iron-based alloy is Alloy 42 that is a Fe—Ni-based alloy. The copper-based alloy is superior over the iron-based alloy in terms of thermal conductivity and adhesion strength with thermosetting resin.

With a tendency of a semiconductor package toward small size, high speed, and multiple functions, the number of pins of the lead frame strip 10 may increase and the lead's width and pitch may be reduced. To improve precision of position and shape of the lead in terms of reliability, precise manufacturing may be possible using stamping or etching.

The lead frame strip 10 may be, for example, a ceramic board strip considering heat conductivity. The lead frame strip 10 may also be a Printed Circuit Board (PCB) strip in which various interconnection layers are formed to connect the light-emitting devices 20 with an external power source and epoxy-based resin sheets are formed in multiple layers. The lead frame strip 10 may also be a synthetic resin board strip using resin, glass epoxy, or the like, or a metallic board strip using insulated aluminium, copper, zinc, tin, lead, gold, silver, or the like.

The light-emitting devices 20 are installed on the lead frame strip 10 and form a line while being spaced apart from each other inside the resin molding products 30, respectively. The light-emitting devices 20 are formed of a semiconductor. For example, the light-emitting device 20 may be a green-light-emitting light-emitting diode (LED) or an ultraviolet (UV)-emitting LED which is formed of a nitride semiconductor. The nitride semiconductor may be expressed by a general formula of AlxGayInzN(0≦x≦1, 0<y≦1, 0≦z≦1, X+Y+Z=1).

The light-emitting device 20 may be formed by epitaxial growth of a nitride semiconductor, such as InN, MN, InGaN, AlGaN, or InGaAlN, on a substrate using vapor phase growth, for example, a molecular organic chemical vapor deposition (MOCVD). The light-emitting device 20 may also be formed using semiconductor such as ZnO, ZnS, ZnSe, SiC, GaP, GaAlAs, or AlInGaP as well as nitride semiconductor. These semiconductors may use a stacked structure in which an n-type semiconductor layer, a light-emitting layer, and a p-type semiconductor layer are formed in this order. The light-emitting layer (active layer) may use a stacked semiconductor having multiple quantum wells or a single quantum well or a stacked semiconductor having a double-hetero structure. The light-emitting device 20 may selectively emit light of an arbitrary wavelength.

The resin molding products 30 are injection-molded from the lead frame strip 10 to enclose the light-emitting devices 20, and may use a resin molding material such as thermosetting resin, thermoplastic resin, or the like.

More specifically, the resin molding products 30 may use a modified epoxy resin composition such as an epoxy resin composition, a silicon resin composition, or a silicon modified epoxy resin, a modified silicon resin composition such as epoxy modified silicon resin, a polyimide resin composition, a modified polyimide resin composition, or resins such as polyphthalamide (PPA), a polycarbonate resin, polyphenylene sulfide (PPS), a liquid crystal polymer (LCP), an acrylonitrile butadiene styrene (ABS) resin, a phenol resin, an acryl resin, or a polybutylene terephthalate (PBT) resin.

These resins may contain a light-reflective substance such as titanium oxide, silicon dioxide, titanium dioxide, zirconium dioxide, titanic acid kalium, alumina, aluminium nitride, boron nitride, mullite, or the like.

The resin molding products 30 may be formed of a material which transmits light from the light-emitting devices 20 to outside. The resin molding products 30 may have a transmissivity of about 70% or more, or about 90% or more, with respect to light emitted from the light-emitting devices 20.

The resin molding products 30 may be a light-transmitting sealing resin using a transparent resin or glass having superior durability, such as epoxy resin, silicon resin, acrylic resin, urea resin, or the like.

As illustrated in FIG. 3, the runner and gate member 40 is formed between the resin molding product 30 and its adjacent resin molding product 30 such that the plurality of resin molding products 30 are connected in series. To reduce damage in sides of the resin molding products 30 during cutting and facilitate cutting, the runner and gate member 40 may be formed in the sides of the resin molding products 30 to have a smaller thickness T2 than a thickness T1 of the resin molding products 30.

As illustrated in FIG. 3, the runner and gate member 40 is formed to have the thickness T2 that is smaller than a thickness T3 of the lead frame strip 10. The runner and gate member 40 may be positioned in a space between an extending surface of a top surface 10T of the lead frame strip 10 and an extending surface of a bottom surface 10B of the lead frame strip 10.

Therefore, when a cutting blade of a conventional degating device or a trimming device approaches to cut the runner and gate member 40, the cutting blade moves down first and contacts the lead frame strip 10 earlier than the runner and gate member 40 and then cuts the runner and gate member 40 together or simultaneously with the lead frame strip 10. Thus, the cutting pressure of the cutting blade is distributed to the lead frame strip 10, minimizing damage in the sides of the resin molding products 30. Even when the cutting blade cuts only the runner and gate member 40 as illustrated, without first contacting the lead frame strip 10, damage in the sides of the resin molding products 30 may be minimized due to low cutting pressure because the thickness T2 of the runner and gate member 40 is small.

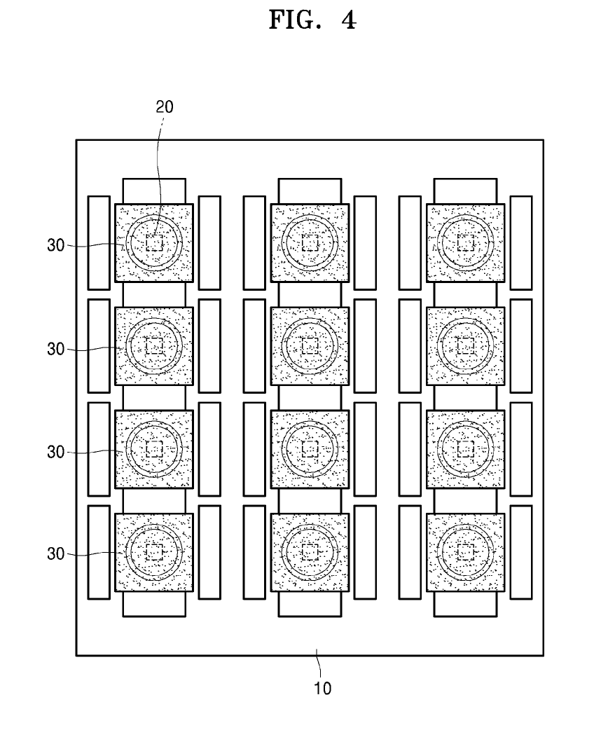

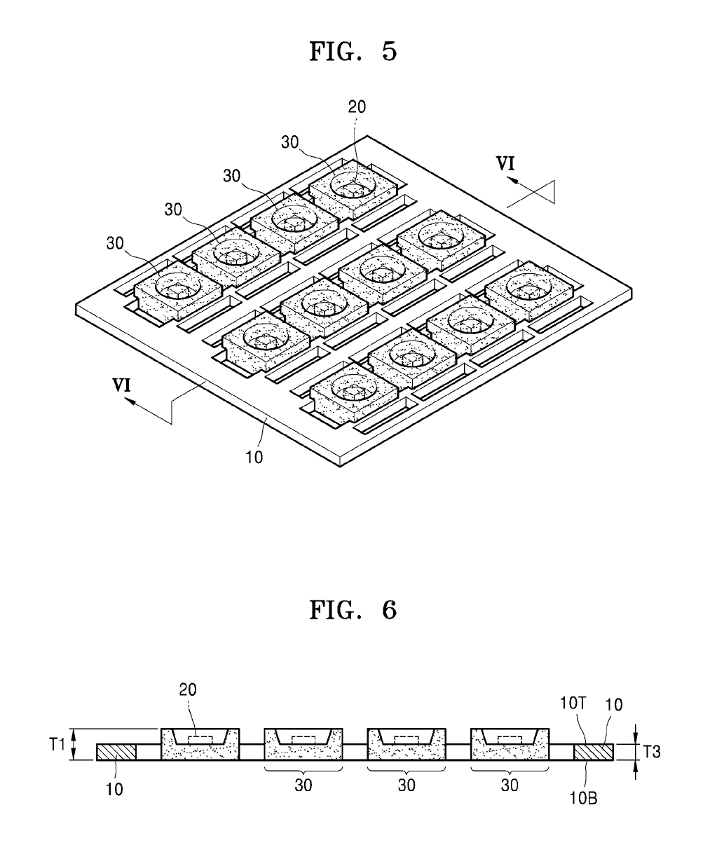

FIG. 4 illustrates a state in which the runner and gate member 40 is removed from the light-emitting device package strip 100 of FIG. 1 by using a cutting process. As illustrated in FIGS. 4 through 6, by using the cutting blade, the runner and gate member 40 may be removed clearly from the light-emitting device package strip 100 of FIG. 1.

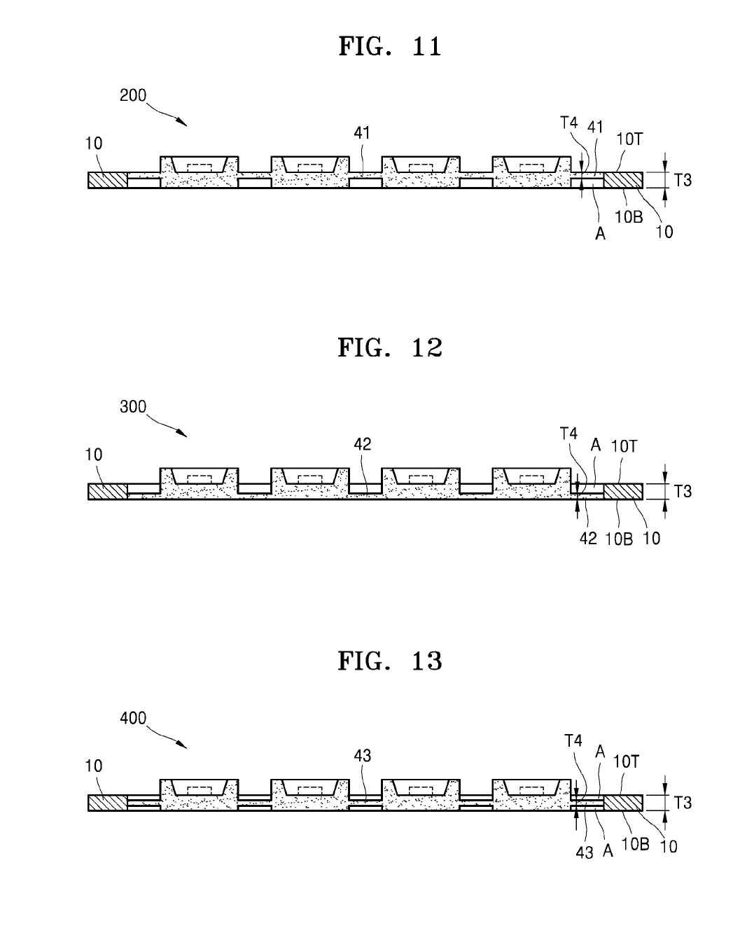

As illustrated in FIG. 11, in the light-emitting device package strip 200 according to some embodiments of the present invention, a runner and gate member 41 is formed to have a thickness T4 that is smaller than the thickness T3 of the lead frame strip 10, and is positioned in an upper portion of an inner space A between the extending surface of the top surface 10T of the lead frame strip 10 and the extending surface of the bottom surface 10B of the lead frame strip 10.

FIG. 12 is a cross-sectional view illustrating a light-emitting device package strip 300 according to some embodiments of the present disclosure.

As illustrated in FIG. 12, in the light-emitting device package strip 300 according to some embodiments of the present invention, a runner and gate member 42 is formed to have the thickness T4 that is smaller than the thickness T3 of the lead frame strip 10, and is positioned in a lower portion of the inner space A between the extending surface of the top surface 10T of the lead frame strip 10 and the extending surface of the bottom surface 10B of the lead frame strip 10.

As illustrated in FIG. 13, in the light-emitting device package strip 400 according to some embodiments of the present invention, a runner and gate member 43 is formed to have the thickness T4 that is smaller than the thickness T3 of the lead frame strip 10, and is positioned in a middle portion of the inner space A between the extending surface of the top surface 10T of the lead frame strip 10 and the extending surface of the bottom surface 10B of the lead frame strip 10.

As illustrated in FIGS. 11 through 13, for each of the light-emitting device package strips 200, 300, and 400, when the cutting blade of the conventional degating device or the trimming device approaches to cut the runner and gate members 41, 42, and 43 respectively, the cutting blade moves down first and contacts the lead frame strip 10 earlier than the runner and gate members 41, 42, and 43 respectively. The cutting blade then cuts the runner and gate members 41, 42, and 43 respectively, together with the lead frame strip 10, such that the cutting pressure of the cutting blade is distributed to the lead frame strip 10, thus minimizing damage in the sides of the resin molding products 30. Even when the cutting blade does not first contact the lead frame strip 10, damage in the sides of the resin molding products 30 may be minimized due to low cutting pressure because the thicknesses T4 of the runner and gate members 41, 42, and 43 respectively are small.

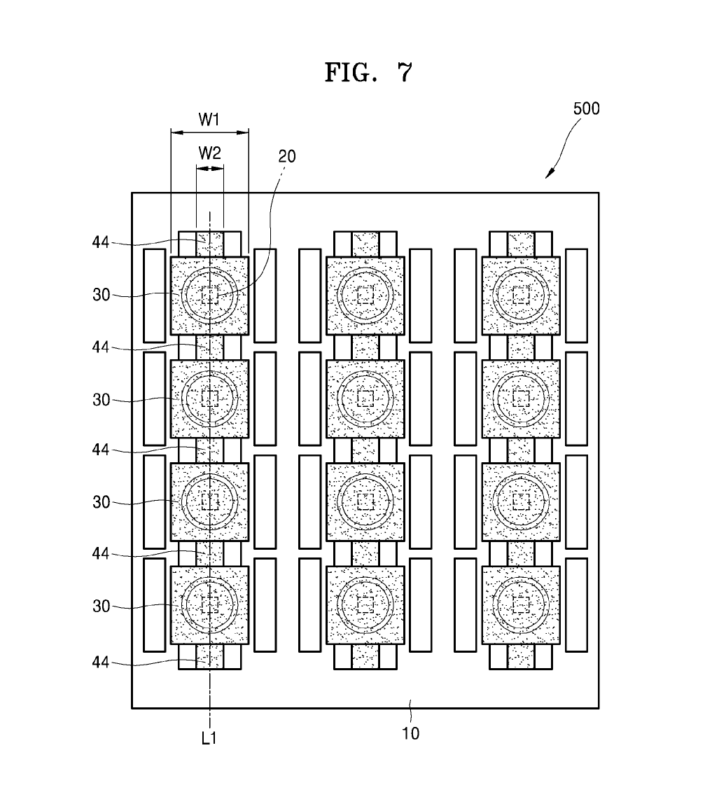

FIG. 7 illustrates a light-emitting device package strip 500 according to some embodiments of the present disclosure.

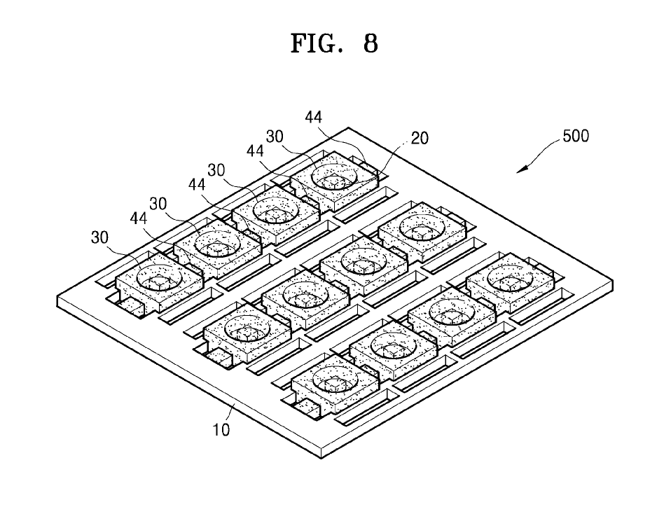

As illustrated in FIGS. 7 and 8, to reduce the cutting pressure of the cutting blade, a runner and gate member 44 may be formed to have a smaller width W2 than a width W1 of the resin molding products 30. For convenience of cutting work, the runner and gate member 44 may be disposed in a line along a center line L1 which connects the center of the resin molding product 30 with the center of its adjacent resin molding product 30.

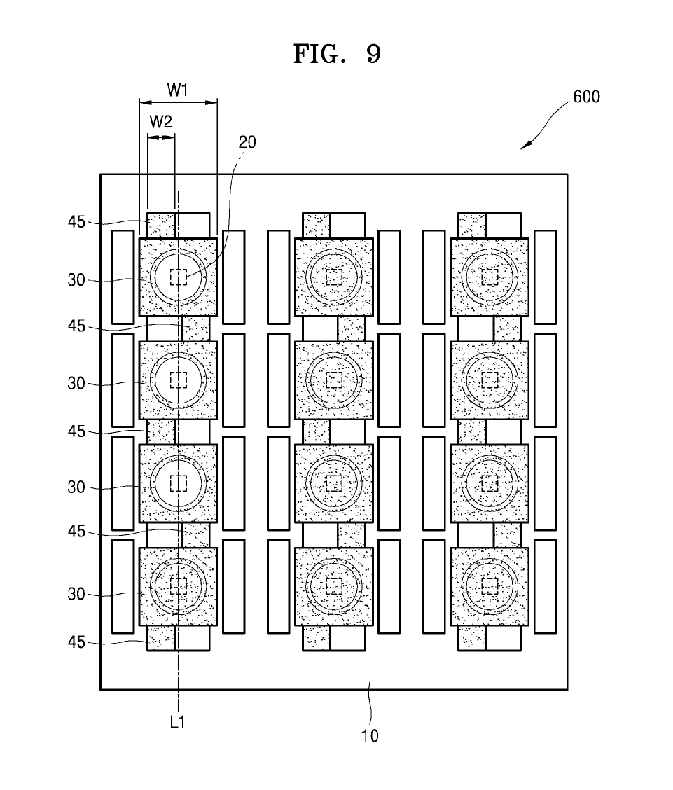

FIG. 9 illustrates a light-emitting device package strip 600 according to some embodiments of the present disclosure.

A runner and gate member 45 is formed to have the smaller width W2 than the width W1 of the resin molding products 30. To prevent an empty space from being formed in a cavity space of the mold by guiding the flow of a resin molding material for forming the resin molding products 30, the runner and gate members 45 may be disposed in a zigzag form. Here, the runner and gate members 45 are formed alternately to the left and right of the center line L1 that connects the centers of the resin molding products 30 with the centers of adjacent resin molding products 30.

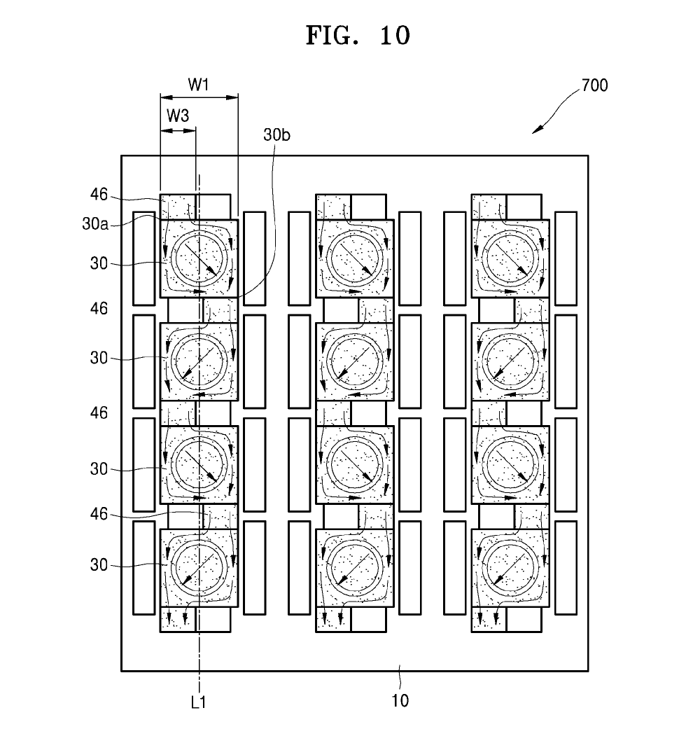

FIG. 10 illustrates a light-emitting device package strip 700 according to some embodiments of the present disclosure. A runner and gate member 46 is formed to have a smaller width W3 than the width W1 of the resin molding products 30, and the resin molding products 30 are generally in a hexahedral shape. To prevent an empty space from being formed in a cavity of the mold by guiding the flow of a resin molding material for forming the resin molding products 30 in a direction from one-side corner to the other-side corner, as indicated by the arrows of FIG. 10, the runner and gate members 46 may be disposed in a zigzag form. Here, the runner and gate members 46 are formed alternately at a left-side corner 30a and a right-side corner 30b of the resin molding products 30 with respect to the center line L1 that connects the centers of the resin molding products 30 with the centers of adjacent resin molding products 30.

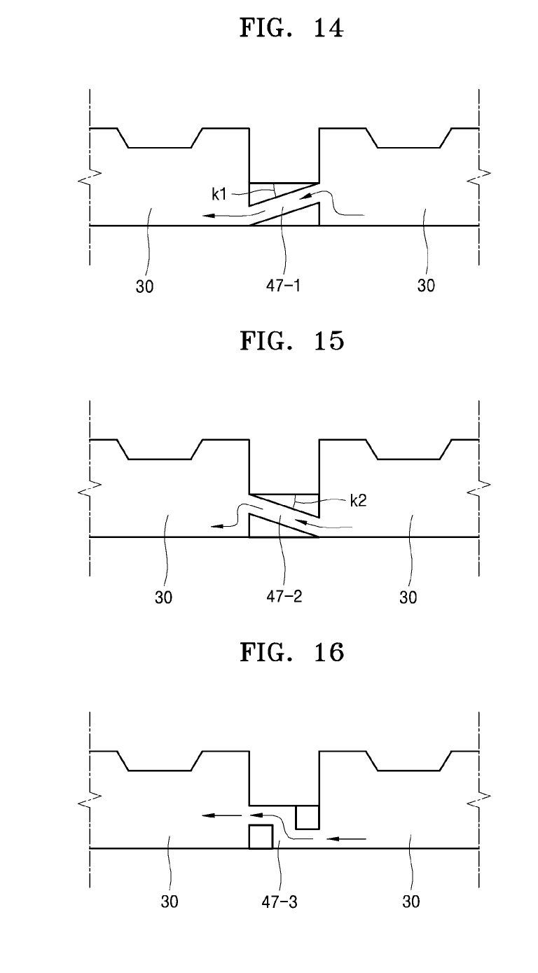

As illustrated in FIG. 14, the runner and gate member 47-1 is formed inclinedly to have a normal-direction inclination K1 with respect to a horizontal plane to accelerate flow of a resin molding material, such that the resin molding material flows down as indicated by the arrows in the mold for forming the resin molding products 30.

As illustrated in FIG. 15, the runner and gate member 47-2 is formed inclinedly to have a reverse-direction inclination K2 with respect to the horizontal plane to accelerate flow of a resin molding material, such that the resin molding material flows up as indicated by the arrows in the mold for forming the resin molding products 30.

As illustrated in FIG. 16, the runner and gate member 47-3 is formed in a straight-bent form to control the flow speed of the resin molding material, such that the resin molding material flows along a bent path as indicated by the arrows in the mold for forming the resin molding products 30.

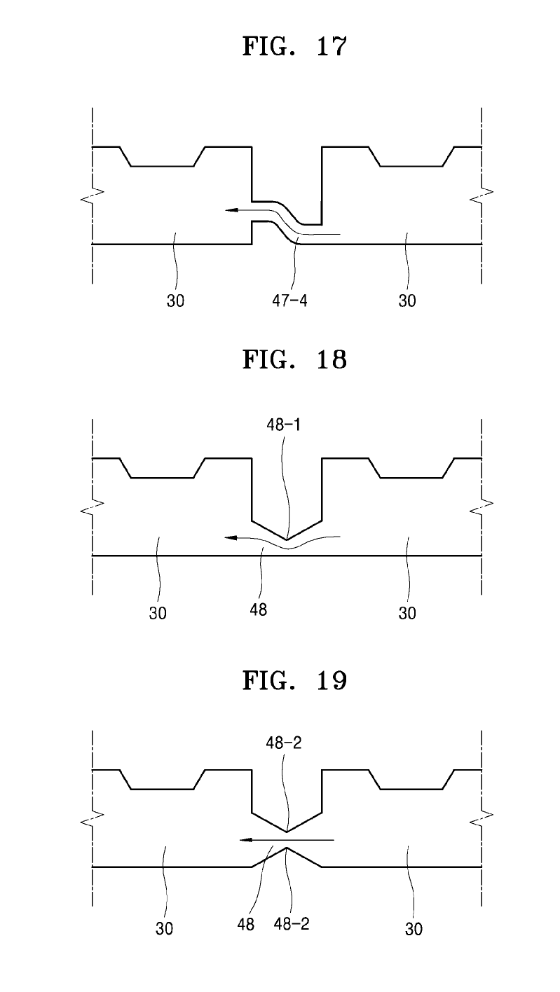

As illustrated in FIG. 17, the runner and gate member 47-4 is formed in a curvilinear-bent form to control the flow speed of the resin molding material, such that the resin molding material flows along a gently-bent path as indicated by the arrows in the mold for forming the resin molding products 30.

As illustrated in FIGS. 18 through 21, a runner and gate member 48 may have neck portions 48-1, 48-2, 48-3, and 48-4 respectively, having thicknesses that are smaller than the other portions to facilitate cutting.

That is, as illustrated in FIG. 18, the neck portion 48-1 may have a V shape formed in an upper portion of the runner and gate member 48.

As illustrated in FIG. 19, the neck portions 48-2 may have a V shape formed in upper and lower portions of the runner and gate member 48.

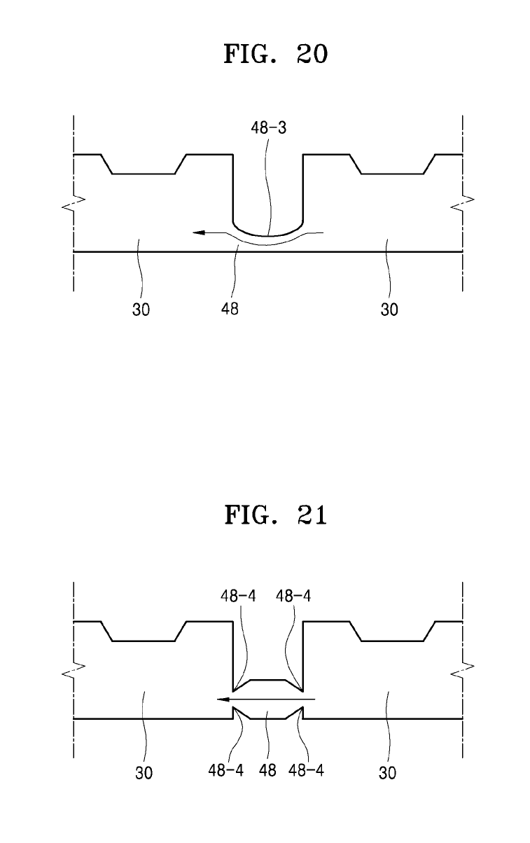

As illustrated in FIG. 20, the neck portion 48-3 may have a U shape formed in the upper portion of the runner and gate member 48.

As illustrated in FIG. 21, the neck portions 48-4 may have a V shape formed in the upper and lower portions of both ends of the runner and gate member 48.

The shapes and positions of the neck portions 48-1, 48-2, 48-3, and 48-4 may be optimally designed according to the type of the mold, standards of the resin molding product 30, the type of the resin molding material, and processing conditions.

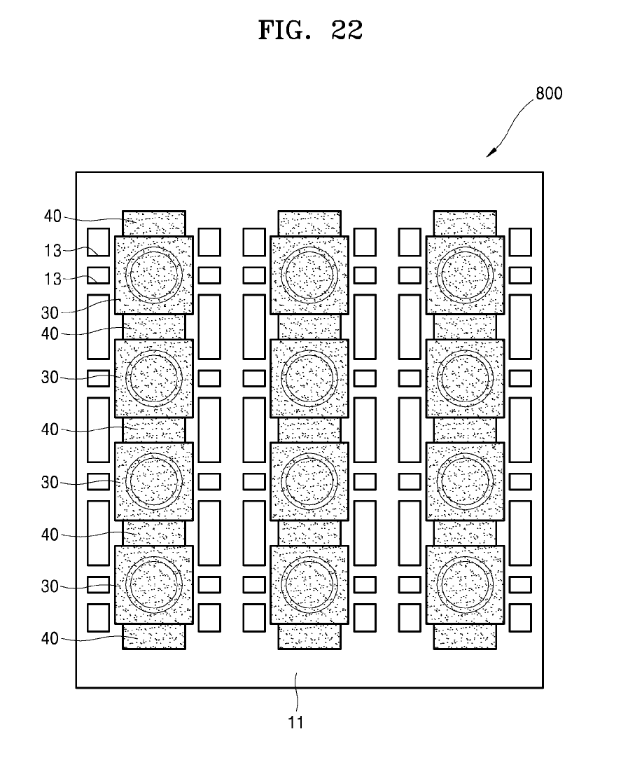

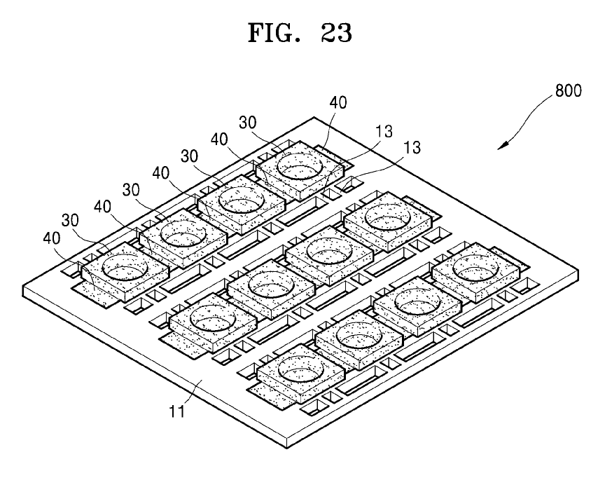

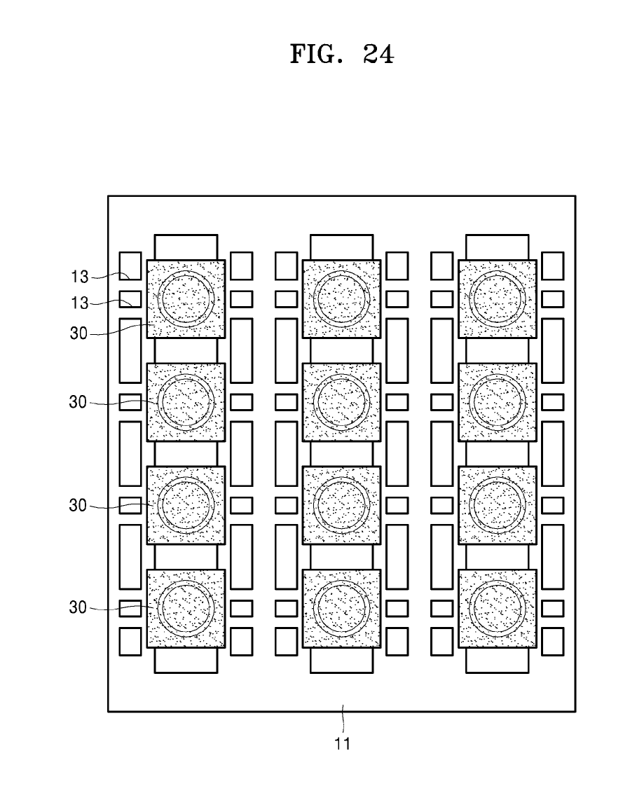

As illustrated in FIGS. 22 through 27, the light-emitting device package strip 800 according to several embodiments of the present disclosure may have a plurality of leads 13 on the lead frame strip 11.

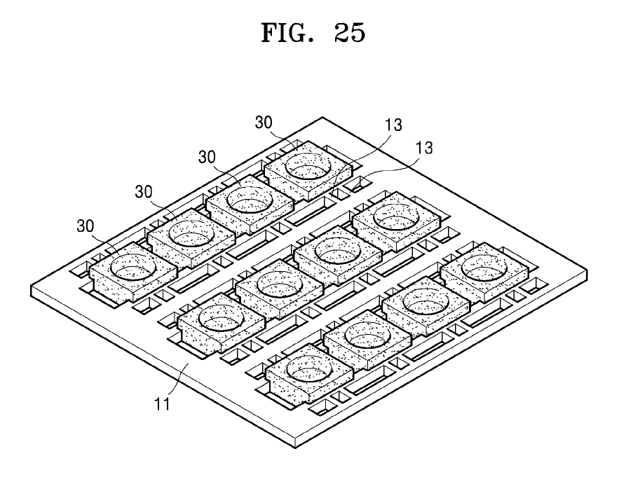

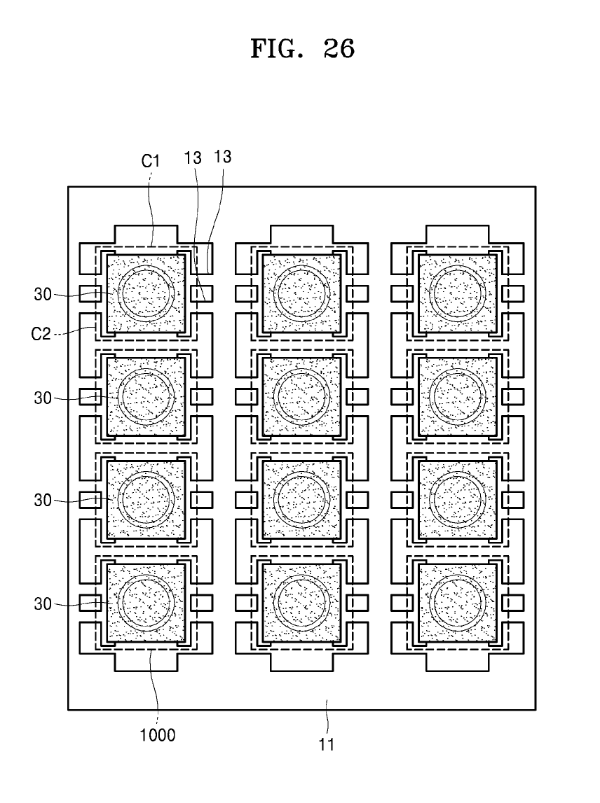

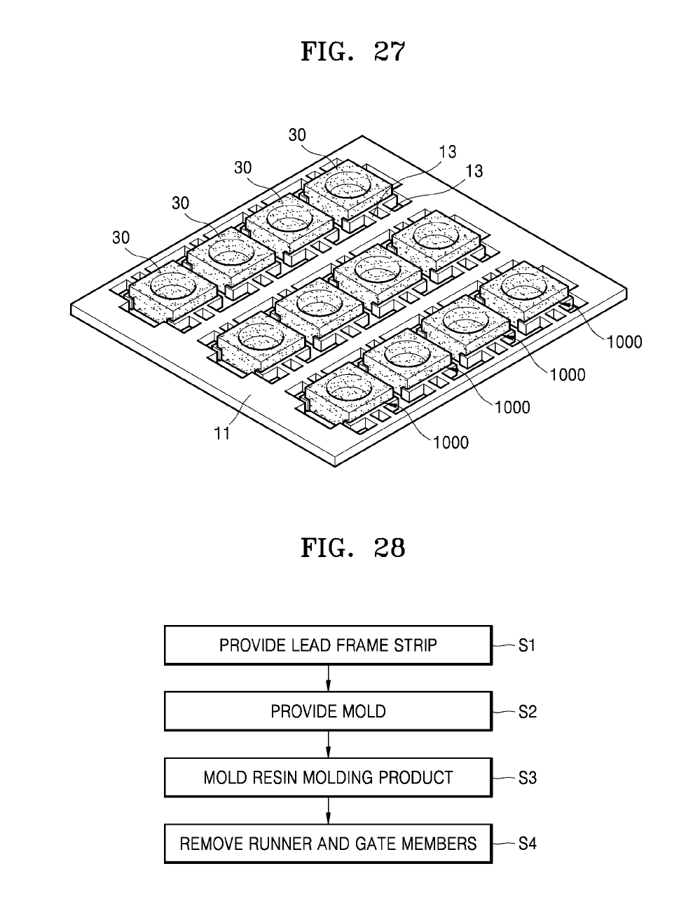

After the runner and gate members 40 are removed from the light-emitting device package strip 800 as illustrated in FIGS. 24 and 25, primary cutting is performed along the bridge cutting line C1 and secondary cutting is performed along the lead cutting line C2 as illustrated in FIGS. 26 and 27, thus obtaining unit light-emitting device packages 1000.

In addition, the type and form of the lead frame strip 10 of the light-emitting device package strip 100 according to the present disclosure may be modified and changed by those of ordinary skill in the art within the technical spirit of the present disclosure.

Referring to FIG. 28 together with FIGS. 1 through 27, a method of manufacturing the light-emitting device package strip 100 according to some embodiments of the present disclosure includes operation S1 of providing the lead frame strip 10. The method also includes operation S2 of providing a mold to form the resin molding products 30 that enclose the plurality of light-emitting devices 20, which are disposed spaced apart from each other in a line in the lead frame strip 10, and the runner and gate members 40 that are formed between the resin molding product 30 and its adjacent resin molding product 30 to serially connect the plurality of resin molding products 30 with each other, as well as on the open ends of the first and last resin molded products in the line of resin molded products, such that the thickness T2 is smaller than the thickness T1 of the resin molding products 30.

Next, operation S3 of molding the resin molding products 30 in the mold is performed, thus manufacturing the light-emitting device package strip 100 according to some embodiments of the present disclosure.

The manufactured light-emitting device package strip 100 according to some embodiments of the present disclosure passes through operation S4 of removing the molded runner and gate members 40 and performing cutting along the bridge cutting line C1 and the lead cutting line C2, such that a separate unit light-emitting device package is manufactured.

The present disclosure is not limited by the foregoing embodiments, and may be modified by those of ordinary skill in the art without departing from the spirit of the present disclosure.

Therefore, the scope of the present disclosure will be defined by the claims and the technical spirit thereof rather than the foregoing description.

What is claimed is:

1. A light-emitting package strip comprising:
a lead frame strip;
a plurality of resin molding products that are injection-molded in the lead frame strip; and
runner and gate members that are disposed between adjacent resin molding products and on end sides of a line of adjacent resin molding products, the runner and gate members each having a smaller thickness than a thickness of the resin molding products to facilitate cutting thereof.

2. The light-emitting package strip of claim 1, wherein the runner and gate members each comprise a smaller thickness than a thickness of the lead frame strip.

3. The light-emitting package strip of claim 2, wherein the runner and gate members are each disposed in a space between an extending surface of a top surface of the lead frame strip and an extending surface of a bottom surface of the lead frame strip.

4. The light-emitting package strip of claim 3, wherein the runner and gate members each comprise a smaller thickness than a thickness of the lead frame strip and are each disposed in one of an upper portion, a middle portion, and a lower portion of an inner space between an extending surface of a top surface of the lead frame strip and an extending surface of a bottom surface of the lead frame strip.

5. The light-emitting package strip of claim 1, wherein the runner and gate members each comprise a smaller width than a width of the resin molding products.

6. The light-emitting package strip of claim 1, wherein the runner and gate members are disposed along a center line that connects the centers of the line of adjacent resin molding products.

7. The light-emitting package strip of claim 1, wherein the runner and gate members are disposed in a zigzag form such that the runner and gate members are disposed alternately to the left and right of a center line that connects the centers of the line of adjacent resin molding products.

8. The light-emitting package strip of claim 1, wherein the resin molding products are generally in a hexahedral shape, and the runner and gate members are disposed in a zigzag form such that the runner and gate members are disposed alternately at a left-side corner and a right-side corner of the resin molding products with respect to a center line that connects the centers of the line of adjacent resin molding products.

9. The light-emitting package strip of claim 1, wherein the runner and gate members each comprise an inclined type that is disposed inclinedly.

10. The light-emitting package strip of claim 1, wherein the runner and gate members each comprise one or more of a straight-bent form, a curvilinear-bent form, and a combination thereof.

11. The light-emitting package strip of claim 1, wherein each runner and gate member comprises a neck portion having a thickness smaller than other portions of the runner and gate member.

12. The light-emitting package strip of claim 11, wherein the neck portions comprise one or more of a V shape, a U shape, and a combination thereof.

13. The light-emitting package strip of claim 11, wherein the neck portions are disposed at both end portions of the runner and gate members.

14. A light-emitting package strip comprising:
a lead frame strip;
a plurality of light-emitting devices that are installed in the lead frame strip and disposed spaced apart from each other in a line;
a plurality of resin molding products that are injection-molded in the lead frame strip to enclose the light-emitting devices; and
runner and gate members that are formed in the resin molding products which contain a light-reflective substance, connecting adjacent resin molding products to each other, and disposed in an inner space between an extending surface of a top surface of the lead frame strip and an extending surface of a bottom surface of the lead frame strip.

15. A method of manufacturing a light-emitting package strip, the method comprising:
providing a lead frame strip;
providing a mold;
disposing the plurality of light-emitting devices spaced apart in a line in the mold;
forming a plurality of resin molded products enclosing the plurality of light-emitting devices;
forming runner and gate members which contain a light-reflective substance between adjacent resin molded products and at the ends of the first and last resin molded products in the line.

16. The method of claim 16, wherein the thickness of the runner and gate members is smaller than the thickness of the resin molded products.

17. The method of claim 16, further comprising removing the runner and gate members from the light-emitting package strip.

18. The method of claim 18, further comprising cutting along bridge cutting lines and lead cutting lines of the light-emitting package strip, providing separate light-emitting device packages.

19. The method of claim 16, wherein the light-reflective substance is one selected from the group consisting of titanium oxide, silicon dioxide, titanium dioxide, zirconium dioxide, titanic acid kalium, alumina, aluminium nitride, boron nitride and mullite.

20. The method of claim 19, wherein the plurality of resin molding products has a transmissivity of 70% or more with respective to light emitted from the plurality of light-demitting devices.
